(19) United States
(12) Patent Application Publication
(10) Pub. No.: US 2011/0303279 A1
(43) Pub. Date: Dec. 15, 2011

(54) Photovoltaic Modules With Reflective Adhesive Films Having Low Susceptibility To Discolouration

(75) Inventor: Uwe Keller, Bonn (DE)

(73) Assignee: KURARAY EUROPE GMBH, Frankfurt (DE)

(21) Appl. No.: 13/155,458

(22) Filed: Jun. 8, 2011

(30) Foreign Application Priority Data
Jun. 11, 2010 (EP) 10165622.6

(51) Int. Cl. H01L 31/0216

(52) U.S. Cl. 136/256

(57) ABSTRACT

Photovoltaic modules are constructed from a laminate consisting of
a) a transparent front covering
b) one or more photosensitive semiconductor layers
c) at least one adhesive film and
d) a rear covering
   wherein at least one adhesive film is equipped to be reflective and contains titanium dioxide pigment with a TiO₂ content of 50 to 94% by weight.

### CROSS-REFERENCE TO RELATED APPLICATIONS

This application claims priority to European Patent Application No. EP 10165622.6 filed Jun. 11, 2010 which is herein incorporated by reference.

### BACKGROUND OF THE INVENTION

1. Field of the Invention

The invention relates to the production of photovoltaic modules using reflective adhesive films that have low susceptibility to discolouration.

2. Background Art

Photovoltaic modules often consist of a photosensitive layer arranged between a glass plate and a back covering. Especially when the back covering is also made of glass, these components are adhered together via one or more intermediate layer films made from polyvinyl butyral (PVB) containing a softening agent.

It is also known that a fraction of the sunlight passes through the photosensitive layers without activating them. In order to improve the quantum yield, particularly the adhesive films arranged behind the photosensitive layers may contain reflective materials such as titanium dioxide, zirconium dioxide or metal pigments. The use of titanium dioxide as the reflective pigment in a PVB film located behind the photosensitive layer is known for example from DE 4337694, WO 2009/071703, US 2007/0235077 or U.S. Pat. No. 5,059,254.

Titanium dioxide is widely used as a white pigment, for example in emulsion paints or to colour PVC profiles. Unfortunately, in the anastase modification, and to a lesser degree in the rutile modification as well, titanium dioxide catalyses the breakdown of a polymer matrix upon exposure to UV radiation, so the titanium dioxide pigments that are available commercially are usually furnished with a coating of inert inorganic materials such as silicon oxides, aluminium oxides or zirconium oxides. These oxides have a lower refractive index, and thus also a substantially lower scattering force than titanium dioxide itself. As the proportions of inert coating increase, the quantity of titanium dioxide in the respective pigment and therefore also the scattering effect of the pigment is reduced. In order to preserve a highly reflective effect and thus a particularly high additive contribution to the photocurrent, titanium dioxide pigments with the highest possible scattering properties, that is to say a particularly high TiO₂ content, are used for photovoltaic applications.

However, it was observed during resistance tests that in highly loaded PVB films, rutile type titanium dioxide with a high TiO₂ content turns blue when exposed to UV radiation, and this significantly reduces the reflectivity of the film. The effect is considerably less pronounced, and only partly reversible, in the border area of the laminate, that is to say where atmospheric oxygen is able to diffuse. Without conjecturing on the merits of any particular theory, it is thought that the observed effect is related to the intermediary states of the electrons, which can only stabilise in this way in the absence of oxygen. When atmospheric oxygen is able to penetrate a photovoltaic module unobstructed through the surface of an adhesive film that is not covered with glass, these effects do not occur in this manner.

A film filled with titanium dioxide in a photovoltaic module thus loses a substantial amount of its reflectivity due to discolouration over the long periods during which a PV module is exposed to solar radiation. Consequently, some of the improved initial performance of the module is also lost over time.

### SUMMARY OF THE INVENTION

An object of the present invention was therefore to provide intermediate layer films containing titanium dioxide for use in photovoltaic modules that are less prone to discolouration and thus exhibit a less substantial loss of reflectivity. It has now surprisingly been found that when titanium dioxide pigment containing a smaller fraction of TiO₂ was used in an intermediate layer film, although the scattering effect/reflectivity achieved is somewhat lower, the loss of reflectivity due to discolouration over time is substantially reduced. A film that is equipped in this way has a longer service life and renders photovoltaic modules more effective over the course of their operating life.

### BRIEF DESCRIPTION OF THE DRAWINGS

FIG. 1 shows the reflectivity versus wavelength before and after UV irradiation of the composition of Example 1.

FIG. 2 shows the reflectivity versus wavelength before and after UV irradiation of the composition of Example 3.

FIG. 3 shows the reflectivity versus wavelength before and after UV irradiation of the composition of Comparative Example 3.

### DETAILED DESCRIPTION OF THE PREFERRED EMBODIMENT(S)

The object of the present invention are therefore photovoltaic modules made from a laminate consisting of
a) a transparent front covering
b) one or more photosensitive semiconductor layers
c) at least one adhesive film and
d) a rear covering
   wherein at least one adhesive film is equipped to be reflective and contains titanium dioxide pigment with a TiO₂ content of 50 to 94% by weight (relative to the pigment used). The titanium dioxide pigment preferably contains TiO₂ in the rutile modification.

The adhesive film equipped for diffuse reflection causes a fraction of the light that passes through the photosensitive semiconductor layer to be reflected back onto it, thereby increasing the efficiency of the module. The use of selected titanium dioxide pigments inhibits discolouration and the increased efficiency is preserved for the lifetime of the module. For example, WO 2009/071703 discloses the use of titanium dioxide pigments with a TiO₂ fraction of 94.5%. Surprisingly, it was found that pigments containing a smaller fraction of TiO₂ possess greater reflectivity after exposure to solar radiation. This was the more surprising because the original reflectivity with a larger fraction of TiO₂ was greater than for pigments with a smaller TiO₂ fraction, which was as expected.

Films used according to the invention manifest retention of reflectivity at 1100 nm of at least 85%, preferably at least 90%, and particularly at least 95% both before and after being exposed to UV radiation for 1000 h according to the test methods described herein.

Films used according to the invention preferably contain titanium dioxide pigment that is coated with one or more compounds from the group of zinc oxide, silicon oxide, aluminium oxide and zirconium oxide. The coating material used is preferably a mixture of silicon oxide and aluminium oxide.

The titanium dioxide pigments used according to the invention preferably have an average particle size of 10-80 nm, more preferably 15-60 nm, and most preferably 20-40 nm.

Consequently, the inorganic portion of the titanium dioxide pigments used for the films according to the invention contains a maximum of 94% by weight TiO₂ The pigments used according to the invention preferably contain a maximum of 93% by weight, yet more preferably a maximum of 92% by weight TiO₂, and most preferably a maximum of 91% by weight TiO₂. However, the TiO₂ content in the titanium dioxide pigments should be more than 50% TiO₂, more preferably more than 70% TiO₂, yet more preferably more than 80% TiO₂, and most preferably more than 85%, otherwise the reflectivity of the film will be inadequate.

Additionally, in order to facilitate uniform inclusion in the film matrix, the titanium dioxide pigments may optionally be subjected to surface treatment with organic compounds. Examples of such compounds are organophosphates, organosulphates, polysiloxanes, or silicone compounds such as polydimethylsiloxane (PDMS). The surface treatment preferably consists of a silicone compound such as PDMS. Polyfunctional alcohols (for example TMP) are less suitable because they are likely to intensify the blue discolouration.

The fraction other than TiO₂ constituting the rest of the titanium dioxide pigments consists of the inorganic and/or organic compounds cited above.

The reflective adhesive film used according to the invention is preferably a single-ply film. However, it may be advantageous if the reflective adhesive film comprises at least one reflective, that is to say pigment-containing, layer (partial film) and at least one non-reflective, that is to say pigment-free layer (partial film). Thus for example one or two outer partial layers may assure the adhesive effect while the reflective partial film containing the reflective pigments and disposed between these two performs the function of reflecting the radiation.

Films with multiple partial layers may be produced by joining prefabricated partial layers or by coextrusion of the partial layers in a single process cycle.

The fraction of titanium dioxide pigments in the reflective adhesive film is preferably at least 5% by weight, more preferably at least 8% by weight or at least 10% by weight, and most preferably at least 12% by weight. An upper limit of 30% by weight should be observed in each case. If the adhesive film is constructed from pigment-free and pigment-containing partial layers, this value refers to the film as a whole, which means that higher concentrations of TiO₂ may be used in the pigment-containing partial layer according to the thickness distribution.

If the reflective intermediate layer consists of at least one pigment-free and at least one pigment-containing partial layer, these partial layers may each have a different or identical composition and/or contain polymer materials.

The material used for the reflective adhesive and partial layers may be the known materials for producing composite laminated glass panes, such as PVC, Geniomer (polydimethylsiloxane/urea copolymer), silicones, polyurethane, ethylene/vinyl acetate (EVA), epoxy casting resins, ionomers, polyolefins, or particularly polyvinyl acetals containing a softening agent or polyvinyl butyrals containing a softening agent.

The films containing polyvinyl acetal with a softening agent preferably include uncrosslinked polyvinyl butyral (PVB), which is obtained by acetalisation of polyvinyl alcohol with butyraldehyde.

The use of crosslinked polyvinyl acetals, particularly crosslinked polyvinyl butyral (PVB), is also possible. Suitable crosslinked polyvinyl acetals are described for example in EP 1527107 B1 and WO 2004/063231 A1 (thermal self-crosslinking of polyvinyl acetals containing carboxyl groups), EP 1606325 A1 (polyvinyl acetals crosslinked with polyaldehydes) and WO 03/020776 A1 (polyvinyl acetals crosslinked with glyoxylic acid). The disclosures of these patent applications are included herein in their entirety by reference.

It is also possible to perform the acetalisation with other or additional aldehydes having 5-10 carbon atoms (such as valeraldehyde for example).

Terpolymers from hydrolysed vinyl acetate/ethylene copolymers may also be used as the polyvinyl alcohol without exceeding the scope of the present invention. These compounds are usually more than 98% hydrolysed and contain 1 to 10 ethylene-based weight units (for example of the type “Exceval” produced by Kuraray Europe GmbH).

Besides the acetal units, polyvinyl acetals also contain units derived from vinyl acetate and vinyl alcohol. The polyvinyl acetals containing softening agent that are used according to the invention preferably include a polyvinyl alcohol fraction of less than 20% by weight, more preferably less than 18% by weight, and most preferably less than 16% by weight. The fraction of polyvinyl alcohol should not be less than 12% by weight.

The fraction of polyvinyl acetate in the polyvinyl acetal is preferably less than 5% by weight, more preferably less than 3% by weight, and most preferably less than 2% by weight. The degree of acetalisation may be calculated arithmetically from the polyvinyl alcohol fraction and the remaining acetate content.

The reflective films used according to the invention preferably have a specific resistance, in order of increasing preference, of at least 1E+11 ohm·cm, 5E+11 ohm·cm, 1E+12 ohm·cm, 5E+12 ohm·cm, 1E+13, 5E+13 ohm·cm, and most preferably 1E+14 ohm·cm in ambient humidity 85% RH at 23° C.

The films used according to the invention, particularly those based on softener-containing polyvinyl acetal, in order of increasing preference, have a maximum softener content of 40% by weight, 35% by weight, 32% by weight, 30% by weight, 28% by weight, 26% by weight, 24% by weight, 22% by weight, 20% by weight, 18% by weight, and 16% by weight, and the softener content should not be less than 15% by weight in order to preserve the film's processability (relative to the total film formulation in each case). Films or photovoltaic modules may contain one or more softeners.

Softeners that are suitable in principle for the polyvinyl acetal-based films used according to the invention are one or more compounds from the following groups:
esters of polyvalent aliphatic or aromatic acids, for example dialkyl adipates such as dihexyl adipate, dioctyl adipate, hexylcyclohexyl adipate, mixtures of heptyl and nonyl adipates, diisononyl adipate, heptylnonyl adipate and esters of adipic acid with cycloaliphatic ester alcohols or with ester alcohols containing ether compounds, dialkyl sebacates such as dibutyl sebacate and esters of sebacic acid with cycloaliphatic ester alcohols or with ester alcohols containing ether compounds, esters of phthalic acid such as butylbenzyl phthalate or bis-2-butoxyethyl phthalate
esters of polyvalent aliphatic or aromatic alcohols or oligoether glycols having one or more unbranched or branched aliphatic or aromatic substituents, for example esters of di-, tri- or tetraglycols with linear or branched aliphatic or cycloaliphatic carboxylic acids; the following may serve as examples of the last group: diethylene glycol-bis-(2-ethylhexanoate), triethylene glycol-bis-(2-ethylhexanoate), triethylene glycol-bis-(2-ethylbutanoate), tetraethylene glycol-bis-n-heptanoate, triethylene glycol-bis-n-heptanoate, triethylene glycol-bis-n-hexanoate, tetraethylene glycol dimethylether and/or dipropylene glycol benzoate
phosphates with aliphatic or aromatic ester alcohols such as tris(2-ethylhexyl)phosphate (TOF), triethyl phosphate, diphenyl-2-ethylhexyl phosphate, and/or tricresyl phosphate
esters of citric acid, Bernstein acid and/or fumaric acid.

One or more compounds selected from the following group are highly suitable softeners for the films based on polyvinyl acetals used according to the invention: di-2-ethylhexyl sebacate (DOS), di-2-ethylhexyl adipate (DOA), dihexyl adipate (DHA), dibutyl sebacate (DBS), triethylene glycol-bis-n-heptanoate (3G7), tetraethylene glycol-bis-n-heptanoate (4G7), triethylene glycol-bis-2-ethylhexanoate (3GO or 3G8) tetraethylene glycol-bis-n-2-ethylhexanoate (4GO or 4G8), di-2-butoxyethyl adipate (DBEA), di-2-butoxyethoxy ethyl adipate (DBEEA), di-2-butoxy ethyl sebacate (DBES), di-2-ethylhexyl phthalate (DOP), di-isononyl phthalate (DINP), triethylene glycol-bis-isononanoate, triethylene glycol-bis-2-propyl hexanoate, tris(2-ethylhexyl)phosphate (TOF), 1,2-cyclohexane dicarboxylic acid diisononyl ester (DINCH), diisononyl adipate (DINA) and dipropylene glycol benzoate.

Especially suitable softeners for the polyvinyl acetal-based films used according to the invention are substances whose polarity, expressed by the formula 100×O/(C+H), is less than/equal to 9.4, wherein O, C and H stands for the number of oxygen, carbon and hydrogen atoms in the respective molecule. The following table lists softeners that are usable according to the invention together with their polarity values according to the formula 100×O/(C+H).

| | | 100 × O/ |
|---|---|---|
| Name | Abbreviation | (C + H) |
| Di-2-ethylhexyl sebacate | (DOS) | 5.3 |
| Diisononyl adipate | (DINA) | 5.3 |
| 1,2-cyclohexane dicarboxylic acid diisonony | (DINCH) | 5.4 |
| lester | | |
| Di-2-ethylhexyl adipate | (DOA) | 6.3 |
| Di-2-ethylhexyl phthalate | (DOP) | 6.5 |
| Dihexyl adipate | (DHA) | 7.7 |
| Dibutyl sebacate | (DBS) | 7.7 |
| Triethylene glycol-bis-2-propyl hexanoate | | 8.6 |
| Triethylene glycol-bis-i-nonanoate | | 8.6 |
| Di-2-butoxyethyl sebacate | (DBES) | 9.4 |
| Triethylene glycol-bis-2-ethyl hexanoate | (3G8) | 9.4 |

The adhesive strength of polyvinyl acetal films on glass is usually adjusted by adding adhesion regulators such as the alkali and/or alkaline earth salts of organic acids, as disclosed in WO 03/033583 A1 for example. Potassium acetate and/or magnesium acetate have proven to be particularly suitable. Polyvinyl acetals often contain alkali and/or alkaline earth salts of inorganic acids, for example sodium chloride, as a result of the production process.

Since alkali metal salts also have an affect on specific resistance, it is expedient to use polyvinyl acetal-based films containing softening agents containing less than 100 ppm, preferably less than 50 ppm and not preferably less than 30 ppm alkali metal ions. This may be achieved with appropriate washing processes of the polyvinyl acetal and by using polyvalent metal salts selected from the group of earth alkali metal, zinc, and aluminium salts as basic stabilisers. Magnesium salts, particularly magnesium acetate, magnesium propionate, magnesium butyrate, magnesium hexanoate, magnesium octoate and magnesium stearate are preferred for this. The reflective film used according to the invention preferably has an alkali titer greater than 0, more preferably greater than 5, yet more preferably greater than 10, and most preferably greater than 15. An alkali titer of 100 should not be exceeded, otherwise the film may take on a yellow discolouration.

The ion mobility, which may be dependent on the water content of the film, and therewith the specific resistance, may be modified by the addition of pyrogenic silica. The softener-containing polyvinyl acetal-based films preferably contain 0.001 to 15% by weight, particularly 2 to 5% by weight pyrogenic SiO₂.

The production and composition of polyvinyl acetal-based films are described in principle in EP 185 863 B1, EP 1 118 258 B1, WO 02/102591 A1, EP 1 118 258 B1 or EP 387 148 B1 for example.

The photovoltaic modules are laminated by fusing the films to obtain an inclusion of the semiconductor layer with the films that is free from bubbles and streaks. The overall thickness of the adhesive films is usually 0.30, 0.38, 0.45, 0.51, 0.76, or 1.14 mm. During the laminating process, films that are used according to the invention fill out the cavities present in the photosensitive semiconductor layers and their electrical connections.

The transparent front covering is typically made from glass or PMMA. The back covering of the photovoltaic module according to the invention may be made from glass, plastic or metal, or composites thereof, wherein at least one of the supports may be transparent. It is also possible to construct one or both coverings in the form of laminated glass plate (that is to say as a laminate of at least two glass panes and at least one PVB film) or in the form of insulating glazing having a gas-filled gap. Of course it is also possible to combine these approaches.

The photosensitive semiconductor layers used in the modules do not have to possess any special properties. Monocrystalline, polycrystalline or amorphous systems may be used.

When thin-film solar modules according to the invention are produced, the photosensitive semiconductors layers are usually applied directly to the transparent covering and bonded with the rear covering with at least one adhesive film according to the invention.

When crystalline or supported solar modules are produced, the solar modules must be encapsulated in adhesive films, that is to say the photosensitive semiconductor layers b) are bonded with the transparent front covering a) via at least one non-reflective adhesive film and with the rear covering d) via at least one adhesive film according to the invention. Except for the reflective pigments, these films preferably have the same composition as the reflective adhesive films.

The laminate body thus obtained may be laminated by any of the methods for laminating with and without prior production of a composite precursor familiar to one skilled in the art.

“Autoclave processes” are performed under elevated pressure of about 10 to 15 bar and at temperatures of 130 to 145° C. for approximately 2 hours. Vacuum bag or vacuum ring methods as described for example in EP 1 235 683 B1 are conducted at about 200 mbar and 130 to 145° C.

The photovoltaic modules according to the invention are preferably manufactured with the aid of vacuum laminators. Vacuum laminators consist of a chamber that can be heated and evacuated, in which composite glass panes can be laminated within 10-60 minutes. Partial vacuums from 0.01 to 300 mbar and temperatures from 100 to 200° C., particularly 130-160° C. have proven effective in practice.

Alternatively, a laminate body fabricated as described above may be compressed between at least one roller pair at a temperature from 60 to 150° C. to form a module according to the invention. Machines of this kind for the production of composite glass panes are known and are normally equipped with at least one heating tunnel before and/or after the first pressing plant in systems with two pressing plants.

Photovoltaic modules according to the invention may be used as façade elements, roof panels, conservatory covering, sound-proofing walls, balcony or balustrade elements, or as components of window surfaces.

### Measuring Methods:

The specific resistance of the film is measured according to DIN IEC 60093 with defined temperature and ambient humidity (23° C. and 85% RH) after the film has been conditioned in this environment for at least 24 h. A type 302 132 plate electrode manufactured by Fetronic GmbH and a ISO-Digi 5 kV resistance meter manufactured by Amprobe were used to perform the measurement. The test voltage was 2.5 kV, the wait time after application of the test voltage until the measured value was recorded was 60 sec. In order to ensure adequate contact between the flat plates of the measuring electrode and the film, the surface roughness R_{z} thereof should not be greater than 10 μm for purposes of measurement according to DIN EN ISO 4287, that is to say the original surface of the PVB film may have to be smoothed by thermal recoining before the resistance measurement is taken.

The polyvinyl alcohol and polyvinyl alcohol acetate content of the polyvinyl acetals was determined in accordance with ASTM D 1396-92. The water or moisture content of the films is determined using the Karl Fischer method.

### Alkali Titer

3 to 4 g of the softener-containing polyvinyl acetal film is dissolved overnight in 100 ml of a mixture of ethanol/THF (80:20) in a magnetic stirrer. 10 ml of a diluted hydrochloric acid (c=0.01 mol/litre) is added to this and the mixture is then titrated potentiometrically with a solution of tetrabutyl ammonium hydroxide (TBAH) in 2-propanol (0.01 mol/litre) against a control sample with a titroprocessor. The alkali titer is calculated as follows:

Alkali titer=ml HCl per 100 g of a sample=(consumption of TBAH control sample−TBAH sample×100 divided by weight of the sample in g.)

### EXAMPLES

Softener-containing polyvinyl butyral films containing titanium dioxide pigment having the composition indicated in the table were investigated with regard to their suitability for use as reflective adhesive film in photovoltaic modules. The films consisted of softened polyvinyl butyral (PVB) having the indicated polyvinyl alcohol (PVOH) content in % by weight and a polyvinyl acetate content of about 1% by weight.

The radiation resistance of the various TiO2 types was compared on glass/glass laminates of the composition:
2 mm Optiwhite (low-iron glass produced by Pilkington
0.76 mm PVB film containing 12.5 percent by weight of the respective titanium dioxide pigment
2 mm Optiwhite

The films were conditioned for 24 h in a climate of 23° C./23% RH before inclusion in the laminate, the glass panes were cleaned with warm demineralised water at 50° C. in a glass washing machine. The laminates were then produced in a rolling/autoclaving process typical for manufacturing composite glass and at a maximum temperature of 140° C.

The laminate samples were irradiated for 1000 h in a “Q-SUN Xenon Test Chamber Model Xe-3-HBS”. Radiation intensity at 340 nm was 0.55 W/m2 with a black tile temperature of 80° C., air temperature of 45° C. and 20% relative humidity. Reflection was measured on a Lambda 950 UV/VIS/NIR-spectrometer manufactured by Perkin Elmer in accordance with EN 410 both before irradiation and 24 h after the samples were removed from the irradiation chamber. The respective reflectivity values from the spectra were read at a wavelength of 1100 nm.

Comparison Examples 1-3 show that the reflectivity values for titanium dioxide pigments including a TiO₂ fraction not according to the invention are significantly worse after irradiation than the pigments according to the invention (Examples 1-4). The comparison between example 2 and comparison example 2 in particular shows that films according to the invention have a higher reflectivity despite their lower TiO₂ fraction, the composition of the adhesive films being otherwise identical.

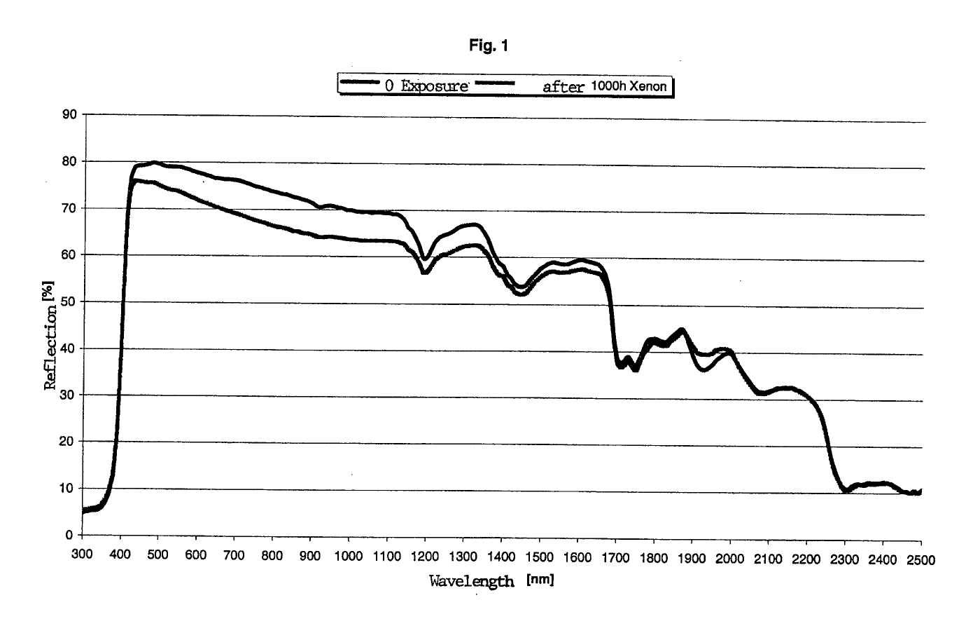

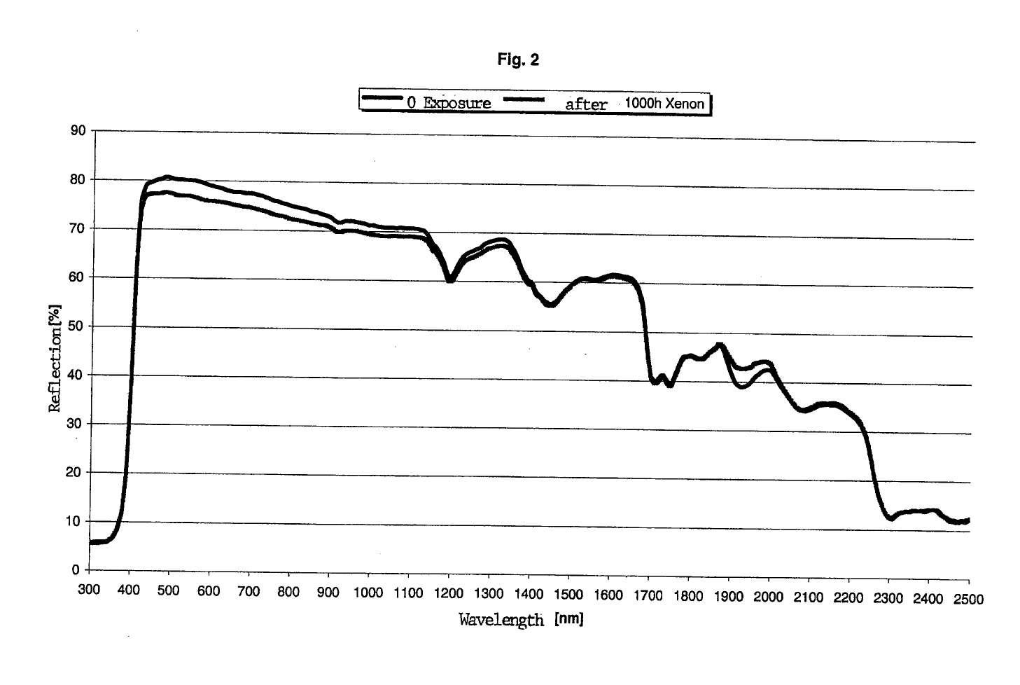

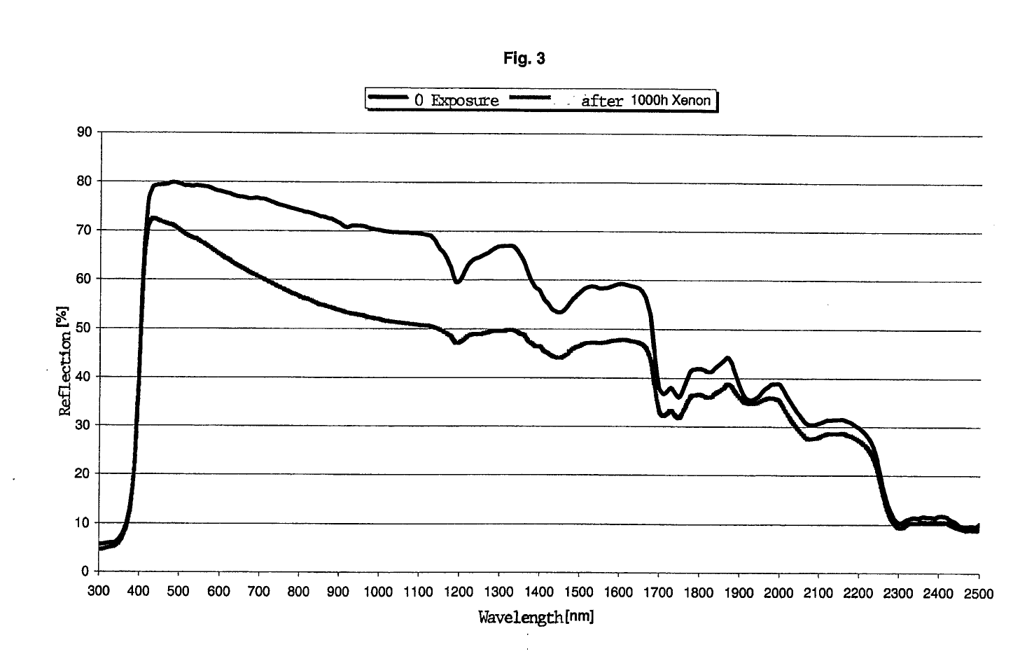

FIGS. 1, 2 and 3 show the reflectivity in % of laminate samples according to examples 1, 3 and comparison example 3 as a function of the wavelength of the scattered light. The upper curves show the reflectivity before irradiation, the lower curves shows the reflectivity after irradiation.

The values in the following table and the figures show that despite a relatively lower scattering capability of the pigment type (according to the manufacturer's specification) intermediate films constructed according to the invention display less discolouration and greater reflectivity after irradiation. Films of this kind are therefore particularly well suited for use in the manufacture of photovoltaic modules.

All information in the Table is given in % by weight relative to the film mixture, that is to say relative to the total (PVB, softener and TiO₂). The PVOH content in the PVB is relative to PVB, the TiO₂ content is relative to the titanium dioxide pigment used. Mg(acetate)2×4 H₂O is added as an anti-adhesion agent.

The titanium dioxides used were obtained from the company Kronos with the product names indicated.

TABLE 1

| | | Ex. 1 | Ex. 2 | Comp Ex. 1 | Comp Ex. 2 | Comp Ex. 3 | Ex. 3 | Ex. 4 |
|---|---|---|---|---|---|---|---|---|
| | Test parameter | K 6121 | K 6122 | K 6123 | K 6124 | K 6125 | K 6126 | K 6127 |
| PVB | % by weight | 64.8 | 64.8 | 64.8 | 64.8 | 64.8 | 64.8 | 64.8 |
| PVOH-content in PVB | % by weight | 20.0 | 20.0 | 20.0 | 20.0 | 20.0 | 20.0 | 14.6 |
| 3G8 | % by weight | 22.7 | 22.7 | 22.7 | 22.7 | 22.7 | 22.7 | — |
| DINCH | % by weight | — | — | — | — | — | — | 22.7 |
| Mg(Ac)₂ × 4H₂O | % by weight | 0.015 | 0.015 | 0.015 | 0.015 | 0.015 | 0.015 | 0.015 |
| Quantity of titanium | % by weight | 12.5 | 12.5 | 12.5 | 12.5 | 12.5 | 12.5 | 12.5 |
| dioxide pigment | | | | | | | | |
| Product name KRONOS | | 2220 | 2222 | 2225 | 2226 | 2450 | 2081 | 2081 |
| Relative scattering | % | 99 | 103 | 101 | 100 | 106 | 88 | 88 |
| capability based on | | | | | | | | |
| manufacturer information | | | | | | | | |
| Organic surface treatment | | PDMS | PDMS | TMP | PDMS | PDMS/TMP | — | — |
| based on manufacturer | | | | | | | | |
| documentation | | | | | | | | |
| TiO₂ content in | % | ≧92.5% | ≧92.5% | ≧94.5% | ≧94.5% | ≧96% | ≧91% | ≧91% |
| accordance with ISO 591 | | | | | | | | |
| based on manufacturer | | | | | | | | |
| documentation | | | | | | | | |
| % reflection at 1100 nm | % | 69 | 69 | 70 | 70 | 70 | 71 | 70 |
| before UV irradiation | | | | | | | | |
| % reflection at 1100 nm | % | 63 | 62 | 55 | 61 | 51 | 69 | 70 |
| after UV irradiation | | | | | | | | |
| % retention of reflection | | 91% | 90% | 79% | 87% | 73% | 97% | 100% |
| at 1100 nm after UV | | | | | | | | |
| irradiation | | | | | | | | |
| Alkali titer of the film | | 15 | 14 | 12 | 13 | 16 | 15 | 14 |
| Electrical resistance in | Ohm × cm | 7.6E11 | 4.8E11 | 3.4E11 | 3.8E11 | 6.4E11 | 1.0E12 | >1.0E14 |
| accordance with DIN IEC | | | | | | | | |
| 60093 | | | | | | | | |

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A laminated photovoltaic module, comprising:
a) a transparent front covering
b) one or more photosensitive semiconductor layers
c) at least one adhesive film and
d) a rear covering
wherein at least one adhesive film is reflective and contains titanium dioxide pigment with a TiO₂ content of 50 to 94% by weight based on the weight of the titanium dioxide pigment.

2. The photovoltaic module of claim 1 wherein the titanium dioxide pigment is coated with at least one or more compounds selected from the group consisting of zinc oxide, silicon oxide, aluminium oxide and zirconium oxide.

3. The photovoltaic module of claim 2, wherein the titanium dioxide pigment is coated with a mixture of silicon oxide and aluminium oxide.

4. The photovoltaic module of claim 1, wherein the titanium dioxide pigments are surface-treated with a silicon compound, a polysiloxane, an organosulphate compound or an organophosphate compound.

5. The photovoltaic module of claim 1, wherein the reflective adhesive film comprises at least one pigment-free partial film and at least one pigment-containing partial film.

6. The photovoltaic module of claim 1, wherein the reflective adhesive film comprises at least one pigment-free partial film and at least one pigment-containing partial film and these partial layers contain the same polymer material.

7. The photovoltaic module of claim 1, wherein the reflective adhesive film contains at least one polyvinyl acetal including a softener.

8. The photovoltaic module of claim 1, wherein the reflective adhesive film has an alkali titer greater than 0.

9. The photovoltaic module of claim 1, wherein the reflective adhesive film contains a polyvinyl acetal with softener, wherein the polyvinyl acetal has a polyvinyl alcohol fraction of less than 20% by weight based on the weight of the polyvinyl acetal.

10. The photovoltaic module of claim 1, wherein the reflective adhesive film includes at least one softener selected from the group consisting of di-2-ethylhexyl sebacate (DOS), 1,2-cyclohexane dicarboxylic acid diisononyl ester (DINCH), diisononyl adipate (DINA), di-2-ethylhexyl adipate (DOA), di-2-ethylhexyl phthalate (DOP), dihexyl adipat (DHA), dibutyl sebacate (DBS), triethylene glycol-bis-2-propyl hexanoate, triethylene glycol-bis-i-nonanoate, di-2-butoxyethyl sebacate (DBES), and triethylene glycol-bis-2-ethyl hexanoate (3G8).

11. The photovoltaic module of claim 1, wherein the reflective adhesive film has a specific resistance of at least 1E+11 ohm·cm in ambient humidity of 85% RH and at 23° C.
